(19) United States
(12) Patent Application Publication
(10) Pub. No.: US 2025/0349771 A1
(43) Pub. Date: Nov. 13, 2025

(54) PADS FOR STACKING DIES WITH HYBRID BONDING AND METHODS THEREOF

(71) Applicant: Tokyo Electron Limited, Tokyo (JP)

(72) Inventor: Kevin Ryan, Albany, NY (US)

(21) Appl. No.: 18/657,511

(22) Filed: May 7, 2024

(51) Int. Cl. H01L 23/00; H01L 23/544; H01L 25/065

(52) U.S. Cl. CPC H01L 24/08; H01L 23/544; H01L 24/80; H01L 25/0657; H01L 2223/54426; H01L 2224/08145; H01L 2224/80031; H01L 2224/8013; H01L 2224/80895; H01L 2224/80896; H01L 2225/06534; H01L 2924/1903

(57) ABSTRACT

A photonic integrated circuit (PIC) device includes a first PIC die including a first plurality of contact pads, each first contact pad includes a first electrical contact region including a first plurality of electrical contacts, a first optical contact region, and a first transition region disposed between the first electrical contact region and the first optical contact region, the first transition region includes a first plurality of dummy contacts.

### TECHNICAL FIELD

The present invention relates generally to semiconductor manufacturing, and, in particular embodiments, to pads for stacking dies with hybrid bonding and methods thereof.

### BACKGROUND

As semiconductor devices become smaller, the interconnect technology used to facilitate communication between the various components of a chip, as well as between different chips in a stacked chip configuration, increases in complexity. Hybrid bonding, which can include direct copper-to-copper bonding and dielectric bonding, is a prominent approach for achieving high-density, high-performance interconnects.

A challenge in hybrid bonding is managing the topography of the bonding interface to ensure uniform and reliable bonds across the entire surface. Additionally, the integration of photonic devices with electronic circuits for high-speed data communication has resulted in the development of optical coupling mechanisms. Evanescent photonic coupling is one such mechanism, which relies on the proximity of waveguides to efficiently transmit optical signals. However, challenges exist in achieving an efficient coupling while maintaining compatibility with standard electrical interconnects.

### SUMMARY

A photonic integrated circuit (PIC) device includes a first PIC die including a first plurality of contact pads, each first contact pad includes a first electrical contact region including a first plurality of electrical contacts, a first optical contact region, and a first transition region disposed between the first electrical contact region and the first optical contact region, the first transition region includes a first plurality of dummy contacts.

A method for fabricating a stacked photonic integrated circuit (PIC) die includes receiving a first PIC die including a first plurality of contact pads, each first contact pad includes a first electrical contact region including a first plurality of electrical contacts, a first optical contact region, and a first transition region disposed between the first electrical contact region and the first optical contact region, the first transition region includes a first plurality of dummy contacts. The method further includes receiving a second PIC die including a second plurality of contact pads, each second contact pad includes a second electrical contact region including a second plurality of electrical contacts, a second optical contact region, and a second transition region disposed between the second electrical contact region and the second optical contact region, the second transition region includes a second plurality of dummy contacts. And the method further includes bonding the first PIC die with the second PIC die to form the stacked PIC die.

And a method for fabricating a photonic integrated circuit (PIC) includes providing a first PIC die including a first plurality of contact pads, each first contact pad includes a first electrical contact region including a first plurality of electrical contacts overfilled with a first metal layer, a first optical contact region covered by a first dielectric layer and the first metal layer, and a first transition region disposed between the first electrical contact region and the first optical contact region, the first transition region includes a first plurality of dummy contacts overfilled with the first metal layer. The method further includes performing a chemical mechanical planarization (CMP) process on the first PIC die to form a first planarized surface. The method further includes providing a second PIC die including a second plurality of contact pads, each second contact pad includes a second electrical contact region including a second plurality of electrical contacts overfilled with a second metal layer, a second optical contact region covered by a second dielectric layer and the second metal layer, and a second transition region disposed between the second electrical contact region and the second optical contact region, the second transition region includes a second plurality of dummy contacts overfilled with the second metal layer. The method further includes performing the CMP process on the second PIC die to form a second planarized surface. And the method further includes bonding the first planarized surface of the first PIC die to the second planarized surface of the second PIC die to form a stacked PIC die.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1E illustrate various schematic cross-sectional views of photonic integrated circuit (PIC) die contact pads at intermediate stages of fabrication, in accordance with an embodiment of the invention;

FIGS. 2A-2B illustrate a schematic cross-sectional view and a schematic top view of a planarized contact pad with a transitional region comprising dummy contacts of varying pad density, in accordance with an embodiment of the invention;

FIGS. 3A-3B illustrate a schematic cross-sectional view and a schematic top view of a planarized contact pad with a transitional region comprising dummy contacts of varying size, in accordance with an embodiment of the invention;

FIGS. 4A-4B illustrate a schematic cross-sectional view and a schematic top view of a planarized contact pad with a transitional region comprising dummy contacts of varying pad density and varying size, in accordance with an embodiment of the invention;

FIG. 5 illustrates a top view of a PIC die comprising a plurality of contact pads, in accordance with an embodiment of the invention;

FIG. 6 illustrates a flowchart of a method of fabricating a stacked PIC die, in accordance with an embodiment of the invention;

FIG. 7 illustrates a flowchart of a method of fabricating a stacked PIC die, in accordance with an embodiment of the invention; and

FIGS. 8A-8D illustrate various schematic cross-sectional views of photonic integrated circuit (PIC) die contact pads at intermediate stages of fabrication in accordance with a conventional method and forms voids.

### DETAILED DESCRIPTION OF ILLUSTRATIVE EMBODIMENTS

In the field of semiconductor photonics, the integration of photonic components with electronic circuits is essential for applications requiring high-speed data transmission and processing. The integration process often involves the bonding of multiple layers of semiconductor substrates, wherein photonic waveguides are patterned to facilitate light signal transmission across different layers and between components.

Photonic waveguides rely on the principle of total internal reflection and utilize precise control over the refractive index contrast between the core and cladding materials. To maintain the integrity of light propagation, it is crucial that these waveguides are formed in a pristine environment, free from any materials or structures that may disrupt evanescent photonic coupling.

During semiconductor processing, it is common practice to utilize dummy contacts to ensure a uniform chemical mechanical planarization (CMP) process. Dummy contacts improve the planarity of the semiconductor wafer by compensating for disparities in pattern density, which would otherwise lead to non-uniformity across the wafer surface after the CMP process. However, the presence of metals (such as the dummy contacts or electrical contacts) near photonic waveguides can introduce significant challenges due to their properties. Metals have high absorption losses for optical signals and can lead to scattering, which is detrimental for photonic waveguide performance.

In regions where photonic waveguides are designed to evanescently couple between bonding interfaces, a keep out zone is used, which is free of any metal features (such as electrical contacts). This keep out zone (or optical contact region) ensures that no metal-induced optical losses occur and that the optical properties of the waveguides remain intact. However, the absence of electrical contacts can affect the local planarity due to CMP roll-off effects, which results in step height differences between the optical contact regions and electrical contact regions.

CMP roll-off refers to the reduction in material removal rate as a function of distance from a patterned feature as a result of the differences in removal rates of the different materials. In areas devoid of electrical contacts, this effect can create a step height difference at the periphery of the keep out zone (or optical contact region). This step height differential can lead to voids when bonding substrates together, thus hindering effective evanescent photonic coupling between stacked photonic integrated circuit (PIC) dies, causing a disconnect in the hybrid bonding electrical interface and possible reliability failure point, and potentially compromising bonding alignment accuracy.

Conventional methods of forming stacked PIC dies have a drastic transition between regions comprising electrical contacts and regions for optical contacts in contact pads where there is a sharp cut-off between the two regions without an intermediary region. As a result, CMP roll-off forms drastic step height differences between the electrical contact regions and optical contact regions (or keep out zones).

Embodiments of this disclosure disclose methods of forming a stacked photonic integrated circuit (PIC) die through void free hybrid and fusion bonding to enable evanescent photonic coupling through dummy contact density gradation.

Embodiments of this disclosure introduce a transition region comprising a plurality of dummy contacts with a changing density (or density gradation) of dummy contacts between an electrical contact region and an optical contact region (or keep out zone) in the contact pads. The density gradation of the dummy contacts between the electrical contact region and the optical contact region of the contact pad may control and thus mitigate CMP roll-off such that there is a smooth transition in height (for example, less than 1 nm per μm of distance for a total length below 8 μm) between the optical contact region and the electrical contact region (rather than a drastic step height, such as a rate greater than 1 nm per μm of distance, or for a total length greater than 8 μm of change if the rate is less than 1 nm per μm of distance). Therefore, the method of forming stacked PIC dies of this disclosure may form stacked PIC dies with void free bonding interfaces using hybrid and fusion bonding to enable the integration of both optical couplers and electrical couplers.

As a result, optical couplers and electrical couplers may be formed without loss in quality of the photonic evanescent coupling due to metal proximity. Further, the use of the transition region of the plurality of dummy contacts with a density gradation between the electrical contact regions and the optical contact regions results in an improvement in bonding alignment between PIC dies. The embodiments described in this disclosure may also be used around alignment markers to enable void free hybrid and fusion bonding in alignment regions. And another benefit of this disclosure is an improvement in bonding front propagation across the bonding interface between PIC dies.

Embodiments provided below describe various methods for forming a stacked PIC die, and in particular, methods using a transition region in contact pads comprising dummy contacts of varying geometric properties to enable a smooth transition between electrical contact regions and optical contact regions for forming the stacked PIC die (which prevents voids forming during bonding and enables evanescent photonic coupling through a combination of hybrid and fusion bonding). The following description describes the embodiments.

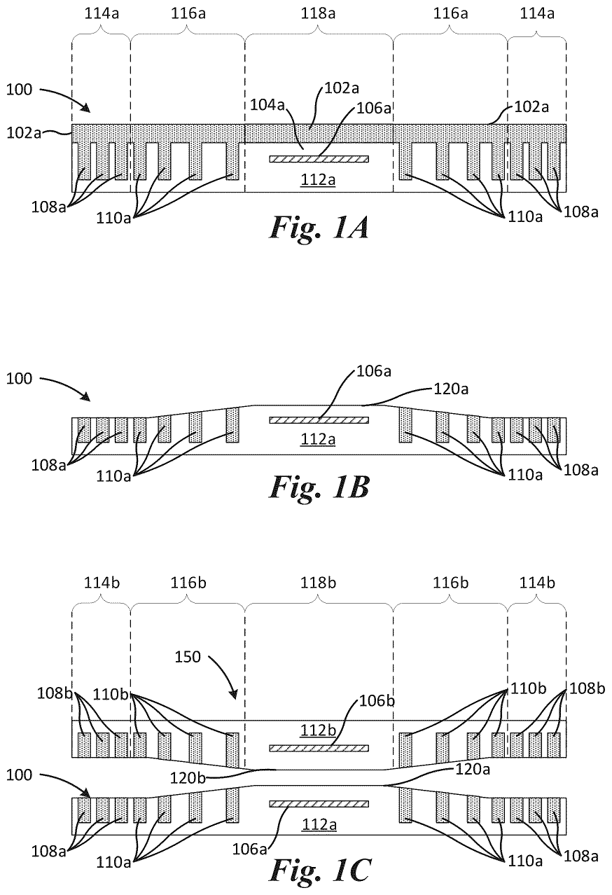

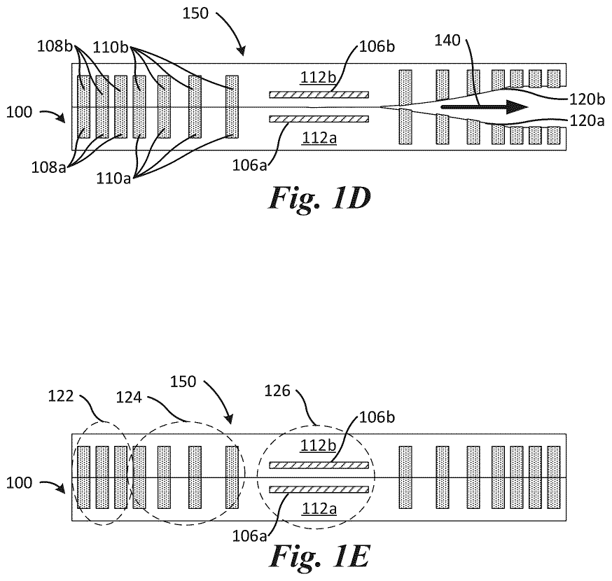

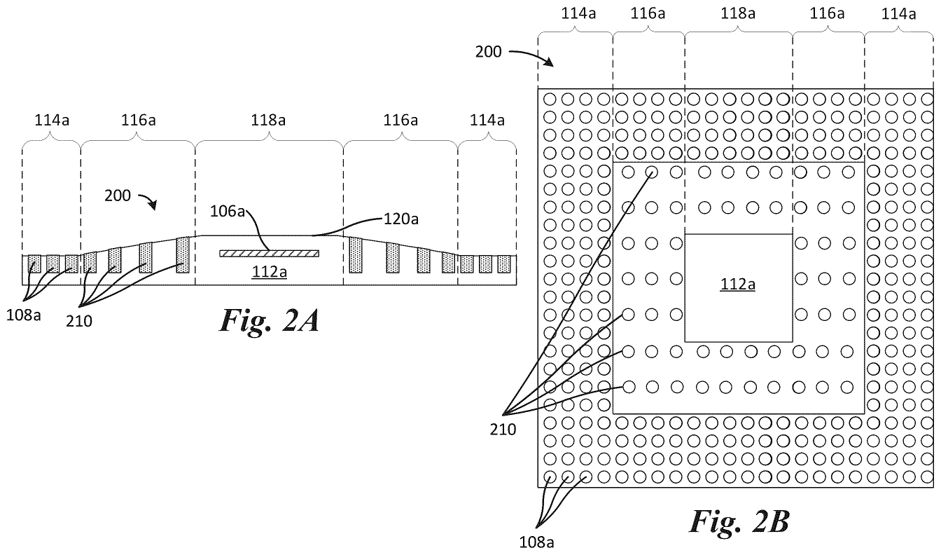

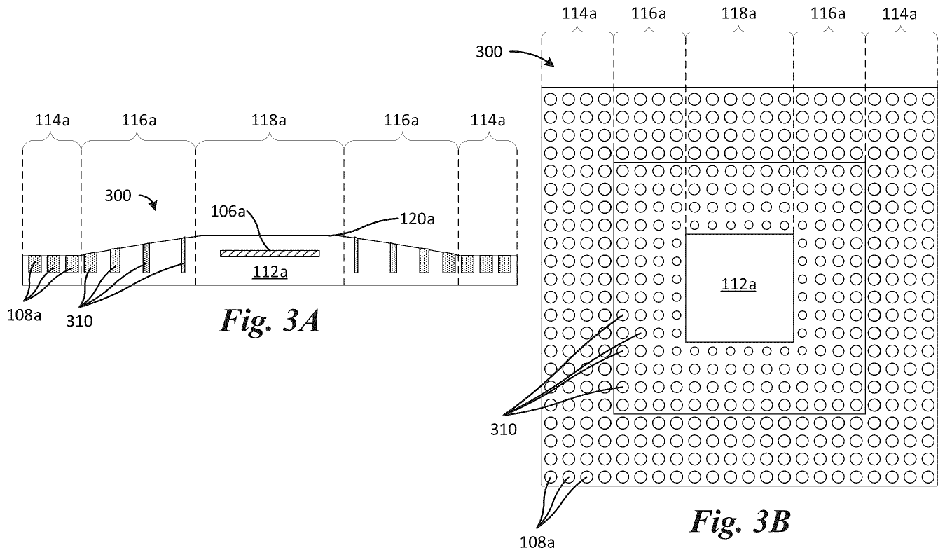

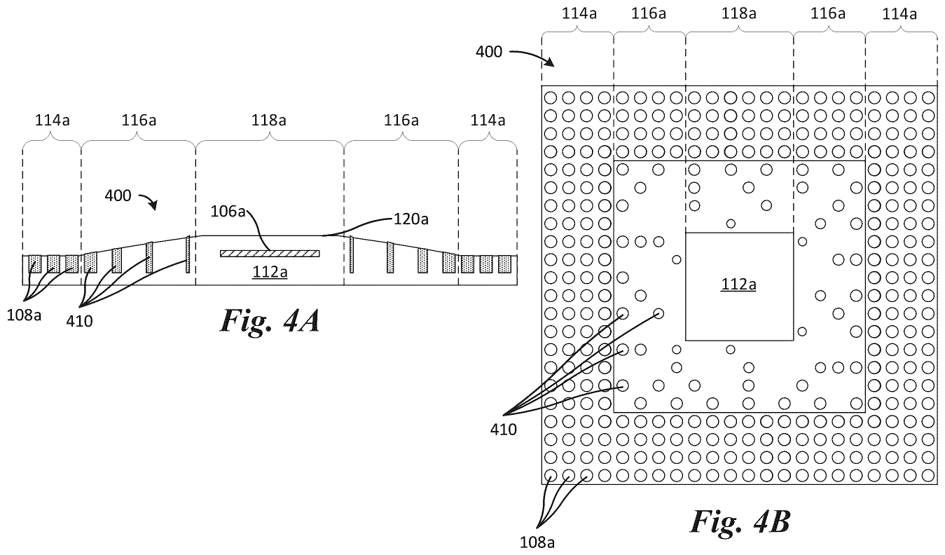

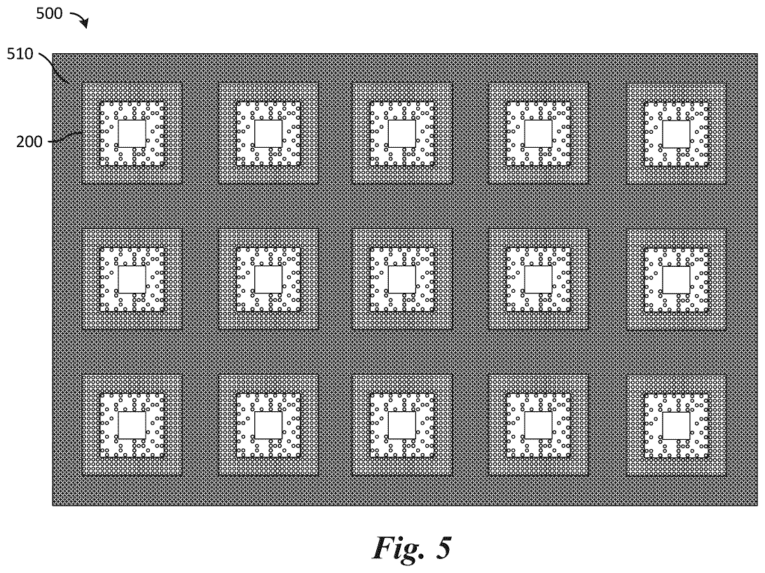

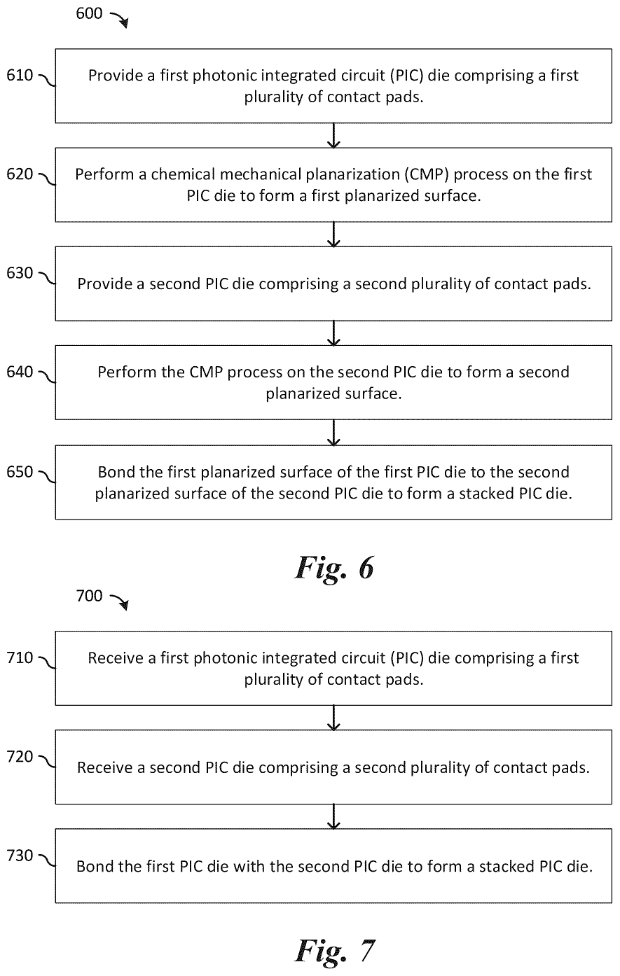

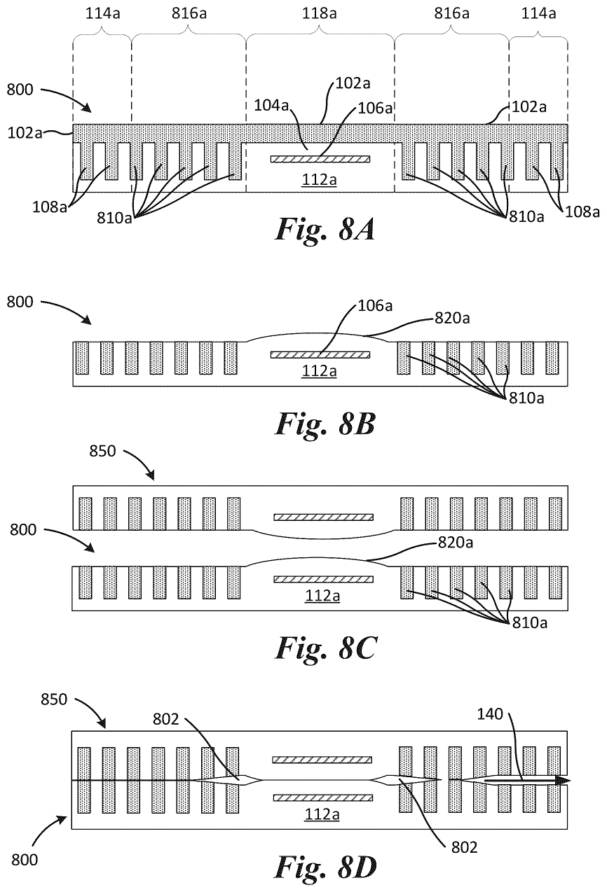

An example chemical mechanical planarization (CMP) process and bonding process between contact pads of a first PIC die and a second PIC die are illustrated in the intermediate stage cross-sectional views of FIGS. 1A-1E. An embodiment contact pad comprising a transition region varying the pad density of dummy contacts is illustrated in the cross-sectional view and the top view of FIGS. 2A-2B. An embodiment contact pad comprising a transition region varying the size of dummy contacts is illustrated in the cross-sectional view and the top view of FIGS. 3A-3B. An embodiment contact pad comprising a transition region varying the pad density of and size of dummy contacts is illustrated in the cross-sectional view and the top view of FIGS. 4A-4B. FIG. 5 illustrates a top view of a PIC die comprising a plurality of contact pads which may be bonded with another PIC die to form a stacked PIC die according to the method of this disclosure. Embodiment methods of forming a stacked PIC die are described using the flowcharts illustrated in FIGS. 6-7. And an example of void formation between surfaces of contact pads which may occur between stacked PIC dies when conventional methods are used is illustrated in FIGS. 8A-8D.

Prior to the processing steps illustrated for planarizing and bonding contact pads between the first PIC die and the second PIC die, a first wafer comprising a plurality of first PIC dies and a second wafer comprising a plurality of second PIC dies may have been processed through a process flow to fabricate the contact pads illustrated in FIGS. 1A-1E. Each tier of the first PIC die and the second PIC die may be formed by processing the first wafer and the second wafer through a sequence of patterning levels comprising, for example, deposition and patterning steps. The process flow for fabricating the first PIC dies in the first wafer and the second PIC die in the second wafer may further include forming optical and electronic components as well as electrical contacts, electrical interconnect elements, dummy contacts, and depositing dielectric layers over the optical components, and depositing a metal layer over the PIC dies (and thus contact pads) to fill the electrical contacts and dummy contacts. Some embodiments may comprise depositing a barrier layer before the metal layer to prevent materials of the metal layer from diffusing into any insulating layers. Electronic components may include resistors, capacitors, and transistors. Optical components may be waveguides, beam splitters or rotators, interferometers, and phase shifters. Electrical interconnect elements such as metal lines, contacts, vias, and TDVs or TSVs may be connecting electrical signals and power supplies during operation.

FIGS. 1A-1E illustrate various cross-sectional views of a first contact pad 100 and a second contact pad 150 through intermediate stages of fabrication that may be used to form various couplings between a first PIC die and a second PIC die to form a stacked PIC die, in accordance with an embodiment of this disclosure. The FIGS. 1A-1E illustrate intermediate stages of fabrication for forming a stacked PIC die, such as using a chemical mechanical planarization (CMP) process to form a planarized surface, and using a bonding process to bond the planarized surfaces of the first PIC die and the second PIC die to form the stacked PIC die.

FIG. 1A illustrates a cross-sectional view schematic diagram of a portion of the first PIC die comprising a first contact pad 100. The first contact pad 100 illustrated in FIG. 1A is produced after depositing a first dielectric layer 104a over a first optical component 106a, and then depositing a first metal layer 102a to cover the first dielectric layer 104a, and fill a first plurality of electrical contacts 108a and a first plurality of dummy contacts 110a. The first contact pad 100 comprises a first electrical contact region 114a, a first transition region 116a, and a first optical contact region 118a. The first plurality of electrical contacts 108a are disposed in the first electrical contact region 114a, the first plurality of dummy contacts 110a are disposed in the first transition region 116a, and the first optical component 106a is disposed in the first optical contact region 118a. The first contact pad 100 further comprises a first isolation layer 112a which comprises various insulating layers disposed between adjacent components (electrical, dummy, and optical) of the first contact pad 100.

Additionally, in various embodiments, a barrier layer (not shown) may be deposited in the unfilled contacts (both electrical and dummy) before being filled using the first metal layer 102a, and the barrier layer (not shown) may be deposited between the first dielectric layer 104a and the first metal layer 102a. Further, the barrier layer (not shown) may be any suitable material for forming a barrier between the first metal layer 102a and the first dielectric layer 104a or the first isolation layer 112a to prevent material of the first metal layer 102a from diffusing into the first dielectric layer 104a or the first isolation layer 112a, such as Ta or TaN.

In various embodiments, the first plurality of electrical contacts 108a may be used to form electrical couplings between PICs of the first PIC die and the second PIC die. Similarly, the first plurality of dummy contacts may be used to form dummy couplings between the first PIC die and the second PIC die. Further, the first optical component 106a may be used to form an optical coupling between PICs of the first PIC die and the second PIC die. An example of an electrical coupling is a pair of through silicon vias (TSVs) in physical contact, and an example of an optical coupling may be a pair of dielectric waveguides positioned in close proximity to each other for evanescent photonic coupling. An example of a dummy coupling is a pair of dummy contacts (or dummy features) in physical contact. Another example of an electrical coupling is a pair of through dielectric vias (TDVs) in physical contact.

In an embodiment, the optical component 106a may be a dielectric waveguide, which may be used to form an evanescent photonic coupling with another dielectric waveguide disposed in the second PIC die. The first dielectric layer 104a may be a combination of various insulating layers deposited during processing the first wafer or included in the starting material for the first wafer.

A region a light wave is confined in a waveguide is commonly referred to as a core of the waveguide. For confinement by total internal reflection (TIR), a refractive index of the core has to be greater than that of any dielectric material adjacent to the core. While the light is confined in the core of the waveguide, there is typically an evanescent EM field in the neighboring lower refractive index dielectric material adjacent to the core, referred to as a cladding of the waveguide. In an embodiment where the first optical component 106a is a planar waveguide that confines the light wave by TIR, the first optical component 106a comprises an optical material having a higher refractive index than that of the material of the first dielectric layer 104a adjacent to the first optical component 106a. For example, if the dielectric material adjacent to the first optical component 106a comprises silicon oxide then, in various embodiments, the first optical component 106a may comprise high resistivity (HR) silicon (also referred to as undoped silicon), silicon nitride, or silicon oxynitride.

In some embodiments, the optical material for the first optical component 106a may comprise silicon nitride and the material for various layers of the isolation layer 112a may comprise silicon oxide. The various layers in the isolation layer 112a may be formed, by depositing, for example, silicon oxide using a suitable deposition technique, such as low pressure chemical vapor deposition (LPCVD), plasma-enhanced chemical vapor deposition (PECVD), and high density plasma chemical vapor deposition (HDP-CVD). Similarly, in various embodiments, the first metal layer 102a may be deposited through a suitable deposition process known in the art. The first metal layer 102a may be a metal suitable for forming the first plurality of electrical contacts and the first plurality of dummy contacts 110a, such as copper, tungsten, ruthenium, cobalt, or molybdenum.

The first transition region 116a comprises the first plurality of dummy contacts 110a. In the embodiment illustrated in FIGS. 1A-1E, the first plurality of dummy contacts 110a decreases the pad density of dummy contacts from the first electrical contact region 114a to the first optical contact region 118a to form a density gradation between the first electrical contact region 114a and the first optical contact region 118a of the first contact pad 100. Other embodiment methods for forming a density gradation between the electrical contact regions and optical contact regions are described using FIGS. 2A-2B, FIGS. 3A-3B, and FIGS. 4A-4B.

After receiving a first PIC die comprising a first plurality of the first contact pad 100 illustrated in FIG. 1A, the method of forming a stacked PIC die of this disclosure performs a chemical mechanical planarization (CMP) process followed by a barrier removal process (to remove the barrier layer over the first dielectric layer 104a) and subsequent buffing process to form a first planarized surface, such as described using FIG. 1B. Embodiments may also comprise a bulk metal removal process. The barrier removal process may be any suitable conventional barrier removal process, and the subsequent buffing process may be any suitable conventional buffing process.

FIG. 1B illustrates a cross-sectional view of the portion of the first PIC die comprising the first contact pad 100 after using a chemical mechanical planarization (CMP) process, barrier removal process, and subsequent buffing process on the first PIC die to form a first planarized surface 120a. The method of forming a stacked PIC die of this disclosure uses contact pads with varying properties of the plurality of dummy contacts in the transition regions to smoothly transition from the electrical contact regions and the optical contact regions. The embodiment illustrated in FIG. 1B comprises the first plurality of dummy contacts 110a which vary the pad density of the first transition region 116a. As is illustrated for the first contact pad 100 in FIG. 1B, the CMP process, barrier removal process, and subsequent buffing process planarized the first PIC die to form a first planarized surface 120a on the first PIC die. Various embodiments, in addition to the CMP process, barrier removal process, and subsequent buffing process, may further comprise a bulk metal removal process, which may be any suitable conventional bulk metal removal process. And in those embodiments, the bulk metal removal process may have also been used in the formation of the first planarized surface 120a.

The planarization of the first PIC die results in the removal of the first metal layer 102a and the shaping of the first dielectric layer 104a to form the first planarized surface 120a due to CMP roll-off. The first planarized surface 120a extends across the entire surface of the first PIC die comprising the first contact pad 100 of FIG. 1B. The smooth transition between the first optical contact region 118a and the first electrical contact region 114a is a result in the CMP process planarizing the different materials of the various regions at different rates due to the density gradation of metal material in the first transition region 116a. For example, in an embodiment where the first dielectric layer 104a comprises silicon oxide and the first metal layer 102a comprises copper, the CMP process removes copper at a faster rate than silicon oxide. In that embodiment, the CMP process removes material from portions of the first transition region 116a comprising more copper (portions with more dummy contacts) faster than the CMP process removes material from portions of the first transition region 116a comprising more silicon oxide (portions with fewer dummy contacts). The result is a smooth transition in height between the first electrical contact region 114a and the first optical contact region 118a, and the CMP process forms the first planarized surface 120a.

The first planarized surface 120a may be formed using a conventional CMP process. During the CMP process, the first wafer comprising a plurality of first PIC dies each comprising a first plurality of the first contact pads 100 is pressed against a rotating polishing pad that is wetted by a slurry containing abrasive and chemical agents. The slurry is carefully formulated to facilitate the planarization process through a combination of chemical reactions and mechanical abrasion. The chemicals in the slurry react with the material on the first wafer surface (such as the material of the first metal layer 102a and the material of the first dielectric layer 104a) to soften or oxidize it, making it more susceptible to removal, while the abrasive particles abrade the raised areas of the surface to physically wear them down. The relative motion between the first wafer and the pad, along with the applied pressure and temperature, are closely controlled to ensure uniform material removal in the first electrical contact regions 114a of the plurality of first PIC dies, and a gradient of material removal in the first transition regions 116a and first optical contact regions 118a of the plurality of first PIC dies.

In various embodiments, pad parameters may be chosen with regard to the materials of the layers to be planarized and optimize the CMP process. The pad parameters may comprise different combinations of pad type (such as hard or soft), and pad conditioner type. The CMP process may be further optimized by configuring the pad parameters and the slurry. Optimization of the CMP process, barrier removal process, and subsequent buffing process may be accomplished by configuring the slurry and pad parameters, as well as barrier removal properties, and parameters of the buffing process (which may mostly comprise a mechanical process on a soft pad). The optimization of the specific CMP process, barrier removal process, and subsequent buffing process enables the formation of the smooth transition in step height between the first electrical contact region 114a and the first optical contact region 118a using the density gradation of the first transition region 116a. And as a result, an optimization recipe comprising the various parameters described above for the CMP process, barrier removal process, and subsequent buffing process in conjunction with the density gradation design factors of the dummy contacts in transition regions, enables the formation of stacked PIC dies comprising both hybrid bonding and photonic coupling in accordance with embodiments of this disclosure.

As mentioned above, the planarization rate of the material in the first dielectric layer 104a is different than the planarization rate of the material in the first metal layer 102a. As a result, a step height difference between the first optical contact region 118a and the first electrical contact region 114a would be formed due to the difference in the planarization rates of the different materials. The first transition region 116a has a varying planarization rate across the first plurality of dummy contacts 110a because of the density gradation (the varying pad density going from more dense near the first electrical contact region 114a to less dense near the first optical contact region 118a). As a result of the density gradation of the first plurality of dummy contacts 110a in the first transition region 116a, a smooth transition in height is formed between the first electrical contact region 114a and the first optical contact region 118a. And after forming the first planarized surface 120a across the plurality of first PIC dies comprising the plurality of first contact pads 100, the same CMP process may be performed on a second wafer comprising a plurality of second PIC dies comprising a plurality of second contact pads to form a second planarized surface, such as described using FIG. 1C.

FIG. 1C illustrates a cross-sectional view of a portion of a first PIC die comprising the first contact pad 100 disposed beneath a portion of a second PIC die comprising a second contact pad 150, where the second contact pad 150 has been processed through a similar CMP process, barrier removal process, and subsequent buffing process to form a second planarized surface 120b across the second PIC die. Various embodiments, in addition to the CMP process, barrier removal process, and subsequent buffing process, may further comprise a bulk metal removal process, which may be a suitable conventional bulk metal removal process.

The second contact pad 150 comprises a second electrical contact region 114b, a second transition region 116b, and a second optical contact region 118b. Similar to the first contact pad 100, the second electrical contact region 114b comprises a second plurality of electrical contacts 108b which may be as similarly described for the first plurality of electrical contacts 108a, the second transition region 116b comprises a second plurality of dummy contacts 110b which may be as similarly described for the first plurality of dummy contacts 110a, and the second optical contact region 118b comprises a second optical component 106b which may be as similarly described for the first optical component 106a. The second contact pad 150 further comprises a second isolation layer 112b, which may be as described for the first isolation layer 112a.

After preparing the first planarized surface 120a of the first PIC die and the second planarized surface 120b of the second PIC die, and after aligning the first PIC die and the second PIC die such that alignment markers between the two are properly oriented, the processing may proceed in bonding the two planarized surfaces in order to form the stacked PIC die of semiconductor devices.

The bonding process couples the first PIC die to the second PIC die by forming the couplings (electrical, optical, and dummy) that have been designed to transmit and receive signals, power supply, and reference voltages between the first PIC die and the second PIC die.

In order to form the optical coupler that couples optical signals across the boundary between the two dies of the stacked PIC die, the first optical component 106a is positioned proximate the second optical component 106b. Thus, the bonding includes aligning the first PIC die with the second PIC die prior to performing a bonding process that physically couples the two dies. For wafer to wafer bonding, the first wafer may be aligned to the second wafer. Thus, the placements of the plurality of first PIC dies in the first wafer matches the placements of the plurality of second PIC dies in the second wafer such that aligning the first wafer to the second wafer results in aligned pairs of dies, each pair comprising one first PIC die and one second PIC die. Of course, the placement of the first optical component 106a in each first PIC die matches the placement of the second optical component 106b in each second PIC die, such that aligning each first PIC die to its respective second PIC die aligns the first optical component 106a to the second optical component 106b over a coupling length. Note that for die to wafer or die to die bonding, the individual dies being bonded to form a stacked die will be aligned to each other.

With the dies aligned, bonding may be performed using a bonding process suitable for bonding the first planarized surface 120a to the second planarized surface 120b. Established bonding processes are used in the embodiments in this disclosure.

A fusion bonding process (also known as direct bonding process) may be used to bond various combinations of dielectric and semiconductor surfaces (e.g., silicon oxide to silicon oxide or silicon to silicon oxide, and the like). The fusion bonding process may bond together regions of the first PIC die and the second PIC die comprising the dielectric and semiconductor surfaces, such as the optical contact regions, and the semiconducting regions over the rest of the surface of the PIC dies. This bonding process is based on two clean and smooth surfaces adhering together by spontaneously formed chemical bonds without any intermediate adhesive material. Generally, the fusion bonding process requires that the bonding surfaces are smooth, i.e., RMS surface roughness is less than about 0.5 nm. The bond formation is initiated by applying pressure and, even at room temperature, bonds may start forming as soon as the surfaces are brought in atomic contact. Typically, the planarized and aligned first PIC die and second PIC die are pre-bonded at a low temperature and the bond strength enhanced by annealing at an elevated temperature. Without any a priori surface activation step, the anneal temperature may be very high, for example, between 700° C. to 1100° C. This is often unacceptable for pre-processed dies. A lower anneal temperature also helps reduce mechanical stress caused by thermal expansion and contraction. In order to reduce the anneal temperature, various surface pretreatments may be done to activate the surfaces to be bonded. For example, in some embodiments, a plasma pretreatment may be performed, where the first planarized surface 120a and the second planarized surface 120b may be exposed to plasma prior to aligning the first PIC die with the respective second PIC die.

In regions where the bonding includes metal-to-metal and dielectric-to-dielectric bonding (such as the first electrical contact region 114a to the second electrical contact region 114b and the first transition region 116a to the second transition region 116b), a hybrid bonding process may be used. A hybrid bonding process combines the fusion bonding process with the metal diffusion bonding process (also known as thermo-compression bonding process) into one bonding process.

In the metal diffusion bonding process, two metal surfaces (e.g., Cu—Cu, Au—Au, and Al—Al) are brought into atomic contact and heat and compressive force are applied simultaneously for an extended time, during which there is a diffusion-controlled movement of material between the crystal lattices of metal grains at the interface between two metal surfaces being bonded. The bond is a result of migration of metal atoms from one crystal lattice to the other by the applied force and heat. The force brings the surfaces in closer contact with each other by increasing the contact area, for example, by asperity deformation that reduces micro-voids at the interface. The heat increases the diffusion coefficient by increasing the energy of random lattice vibrations. For example, the metal diffusion process may be used to bond the first plurality of electrical contacts 108a to the second plurality of electrical contacts 108b, and to bond the first plurality of dummy contacts 110a to the second plurality of dummy contacts 110b.

One advantage of hybrid bonding is that optical and electrical couplers may be formed in a single bonding process. The bonding between the dielectric portions may be used to form optical couplers and the bonding between the metallic portions may be used to form electrical couplers and the bonding between the metallic dummy contacts may be used to form dummy couplers. A key benefit of the method of forming a stacked PIC die using the density gradation of dummy contacts in a transition region of this disclosure is the smooth transition between the electrical contact region and the optical contact region enables the PIC dies to be bonded without forming voids. The void free bonding of the PIC dies enables evanescent photonic coupling and electrical couplers to be fabricated on the same stacked PIC die. The difficulty of potential void formation due to the large step height differences identified by the inventors of this disclosure is further described using FIGS. 8A-8D below. Another benefit of the method of forming a stacked PIC die of this disclosure is the improvement in the bond front propagation across the PIC dies, which is described using FIG. 1D.

FIG. 1D illustrate a cross-sectional view of a portion of a first PIC die comprising the first contact pad 100 and a portion of a second PIC die comprising the second contact pad 150 as a bond front 140 propagates across the bonding interface. The first planarized surface 120a of the first contact pad 100 and the second planarized surface 120b of the second contact pad 150 are bonded using a hybrid bonding process to form various couplings between components of the first contact pad 100 and the second contact pad 150.

A benefit of the density gradation of the plurality of dummy contacts in the corresponding transition regions is an improvement in the bonding front 140 propagation during the bonding process to bond the first contact pad 100 of the first PIC die with the second contact pad 150 of the second PIC die. The smooth transition in height between the electrical contact regions and the optical contact regions due to the density gradation of the plurality of dummy contacts enables the bond front 140 to smoothly propagate across the bonding interface of the two PIC dies. In various embodiments, the difference in height between the electrical contact regions and the optical contact regions may be about 10 nm, which corresponds to the height offset between the first plurality of electrical contacts 108a and the second plurality of electrical contacts 108b being about 20 nm. As a result of the height offset being relatively small, the bond front 140 propagates across the surface of the first PIC die and the second PIC die and is able to bring and bond the first electrical contact regions 114a and the second electrical contact regions 114b together to form electrical couplers because of the relatively small amount of pressure to bring the surfaces into contact, the relatively large strength of the bonds formed being capable of maintaining the pressure in those regions, and the gradual (or smooth) change in height affording the ability for the bond front 140 to smoothly propagate across the bond interface.

Conventional methods that incorporate a sharp cut-off between electrical contact regions and optical contact regions result in large step height differences which diminish the ability of the bond front to smoothly propagate across the bonding interface between the PIC dies. Thus, the method of forming a stacked PIC die of this disclosure is capable of bonding PIC dies with a more controlled and improved bond front propagation. In other embodiments, the optical contact regions may instead be alignment mark regions, and the method of this disclosure may also be used in those embodiments to enable an improved bond front propagation across the alignment marks to improve die alignment, which is another benefit of the embodiment methods of this disclosure.

FIG. 1E illustrates a cross-sectional view of a stacked PIC die comprising the first contact pad 100 and the second contact pad 150 after bonding to form various couplings between components of the first contact pad 100 and the second contact pad 150, and without forming voids between the contact pads. A key benefit of the dummy contact density gradation in the first transition region 116a and the second transition region 116b is the CMP roll-off may be controlled to prevent void formation after bonding the first PIC die and the second PIC die. Further, the combination of hybrid and fusion bonding used to bond dies comprising contact pads using density gradation of the dummy contacts enables evanescent photonic coupling and electrical couplings within contact pads of the dies.

The first contact pad 100 and the second contact pad 150 bonded together to form the stacked PIC die formed various couplings between components of the PIC dies. A plurality of electrical couplings 122 is formed from bonding the first plurality of electrical contacts 108a with the second plurality of electrical contacts 108b. A plurality of dummy couplers 124 is formed from bonding the first plurality of dummy contacts 110a with the second plurality of dummy contacts 110b. And an optical coupler 126 is formed from bonding the dielectric layers separating the first optical component 106a and the second optical component 106b to enable an evanescent photonic coupling between the optical components.

In other embodiments, the first optical contact region 118a and the second optical contact region 118b may comprise alignment markers instead of the first optical component 106a and the second optical component 106b. In those embodiments, rather than bonding the first contact pad 100 and the second contact pad 150 to form optical couplings in the optical contact regions, the contact pads may be aligned and bonded using the density gradation to prevent voids from CMP roll-off around the alignment markers, and improve the hybrid and fusion bonding proximal to the alignment markers between the first PIC die and the second PIC die. In various embodiments, the first PIC die and second PIC die may comprise a mixture of contact pads for alignment markings and contact pads for forming hybrid electrical and optical couplers where the contact pads use the density gradation of dummy contacts in transition regions between electrical contact regions and keep out zones (optical contact regions, or alignment mark regions).

The embodiment illustrated in FIGS. 1A-1E used varying dummy pad density for the first plurality of dummy contacts 110a and the second plurality of dummy contacts 110b to achieve the density gradation in the first transition region 116a and the second transition region 116b. Density gradation may be implemented through a variety of embodiments that change different characteristics of the dummy contacts, such as the variation in pad density of the dummy contacts described using the embodiment illustrated in FIGS. 2A-2B, or the variation in size of the dummy contacts described using the embodiment illustrated in FIGS. 3A-3B, or the variation in both pad density (by changing the pitch or pad layout configuration) and size of the dummy contacts described using the embodiment illustrated in FIGS. 4A-4B.

FIGS. 2A-2B illustrate a cross-sectional view and a top view schematic diagram of a first contact pad 200 comprising the first transition region 116a varying the pad density of a plurality of dummy contacts 210 to implement the density gradation, in accordance with an embodiment of this disclosure.

FIG. 2A illustrates a cross-sectional view schematic diagram of the first contact pad 200 with the first transition region 116a varying the pad density of the plurality of dummy contacts 210 to form a smooth transition between the first electrical contact region 114a and the first optical contact region 118a such that voids will not be formed when bonding a first PIC die and a second PIC die. Similarly labeled elements may be as previously described.

As mentioned above, different embodiment methods use different techniques for the density gradation of the plurality of dummy contacts in the transition regions. The embodiment illustrated in FIG. 2A uses a varying pad density of the plurality of dummy contacts 210 in the first transition region 116a to implement the density gradation. As illustrated, the pad density (or number of dummy contacts over an area of the transition region) decreases from the first electrical contact region 114a to the first optical contact region 118a. The pad density is the only variation used to achieve the density gradation in the embodiment illustrated in FIGS. 2A-2B.

FIG. 2B illustrates a top view schematic diagram of the contact pad 200 illustrated in FIG. 2A. As shown, the number of dummy contacts in the plurality of dummy contacts 210 decreases from the first electrical contact region 114a to the first optical contact region 118a. The embodiment illustrated in FIGS. 2A-2B may be for the contact pad 200 comprising elements labeled for the first contact pad, but the contact pad 200 may also be used as a second contact pad on the second PIC die in other embodiments.

FIGS. 3A-3B illustrate a cross-sectional view and a top view schematic diagram of a first contact pad 300 comprising a first transition region 116a varying the size of a plurality of dummy contacts 310 to implement the density gradation, in accordance with an embodiment of this disclosure.

FIG. 3A illustrates a cross-sectional view schematic diagram of the first contact pad 300 with a first transition region 116a varying the size of the plurality of dummy contacts 310 to form a smooth transition between the first electrical contact region 114a and the first optical contact region 118a such that voids will not be formed when bonding a first PIC die and a second PIC die. For example, the plurality of dummy contacts in the first transition region 116a going from the first electrical contact region 114a to the first optical contact region 118a are decreasing in critical dimension of the dummy contact features. As a result, after the CMP process forms the first planarized surface 120a, the first transition region 116a has a smooth transition between the height of the first electrical contact region 114a and the first optical contact region 118a because of the varying planarization rate in the first transition region 116a from the density gradation of the plurality of dummy contacts 300. Similarly labeled elements may be as previously described.

FIG. 3B illustrates a top view schematic diagram of the contact pad 300 illustrated in FIG. 3A. As shown, the size of dummy contacts in the plurality of dummy contacts 310 decreases from the first electrical contact region 114a to the first optical contact region 118a. The embodiment illustrated in FIGS. 3A-3B may be for the first contact pad 300 comprising elements labeled for a contact pad on the first PIC die, but the contact pad 300 may also be used as a second contact pad on the second PIC die in other embodiments.

FIGS. 4A-4B illustrate a cross-sectional view and a top view schematic diagram of a first contact pad 400 comprising a first transition region 116a varying the size of and pad density of a plurality of dummy contacts 410 to implement the density gradation, in accordance with an embodiment of this disclosure.

FIG. 4A illustrates a cross-sectional view schematic diagram of the first contact pad 400 with a first transition region 116a varying a combination of the size of and pad density of the plurality of dummy contacts 410 to form a smooth transition between the first electrical contact region 114a and the first optical contact region 118a such that voids will not be formed when bonding a first PIC die and a second PIC die. Similarly labeled elements may be as previously described.

FIG. 4B illustrates a top view schematic diagram of the contact pad 400 illustrated in FIG. 4A. As shown, the number of dummy contacts in the plurality of dummy contacts 410 and the size of the dummy contacts (such as the critical dimension of the dummy contacts) in the plurality of dummy contacts 410 decreases from the first electrical contact region 114a to the first optical contact region 118a. The embodiment illustrated in FIGS. 4A-4B is described for the first contact pad 400 comprising elements labeled for a contact pad on the first PIC die, but the first contact pad 400 may also be used as a second contact pad on the second PIC die in other embodiments.

Any of the embodiments used to form the density gradation in the transition regions of the contact pads of the PIC dies described using FIGS. 1A-1E, 2A-2B, 3A-3B, and 4A-4B may be used to enable the integration of both optical couplings and electrical couplings without forming voids after bonding PIC dies. An example PIC die which may be bonded with another PIC die using the method of forming a stacked PIC die in accordance with an embodiment of this disclosure is illustrated in FIG. 5.

FIG. 5 illustrates a top view schematic diagram of a first PIC die 500 which may be bonded with a second PIC die to form a stacked PIC die, in accordance with an embodiment of this disclosure. The first PIC die comprises a plurality of first contact pads 200 disposed over a planarized surface of the first PIC die 500. A bridge region 510 may be formed between first contact pads 200 to avoid a sharp transition between regions comprising electrical contacts and regions without either electrical or dummy contacts. In various embodiments, the bridge region 510 comprises both dummy contacts and electrical contacts of the same density and pitch as the contacts in the first electrical contact region 114a for each of the first contact pads 200 disposed over the surface of the first PIC die 500.

In some embodiments, the bridge region 510 comprises only dummy contacts of the same density and pitch as the contacts in the first electrical contact region 114a for each of the first contact pads 200. And in other embodiments, the bridge region 510 comprises only electrical contacts of the same density and pitch as the contacts in the first electrical contact region 114a for each of the first contact pads 200. The bridge region 510 may be populated with either dummy contacts, or electrical contacts, or a mixture such that the bridge region 510 may be planarized at a similar planarization rate as the first electrical contact region 114a for each of the first contact pads 200. As a result, the bridge region 510 comprises minimal, if any, step height difference between the first electrical contact regions 114a of each of the first contact pads 200 due to the planarization of the first PIC die 500.

Still referring to FIG. 5, in various embodiments, layers beneath the first PIC die 500 comprise ICs with both electrical and optical components which may have interconnects with the plurality of first contact pads 200. Other embodiments may use the first contact pad 300 of FIGS. 3A-3B, or the first contact pad 400 of FIGS. 4A-4B in place of the plurality of first contact pads 200. Embodiment methods of forming a stacked PIC die of this disclosure (such as a method of forming a stacked PIC die comprising the first PIC die 500 and a second PIC die) are described using the flowcharts of FIGS. 6-7.

FIGS. 6-7 illustrate example methods of forming a stacked photonic integrated circuit (PIC) die in accordance with embodiments of this disclosure. The methods of FIGS. 6-7 may be combined with other methods and performed as described herein. For example, the methods of FIGS. 6-7 may be combined with any of the embodiments of FIGS. 1A-1E, FIGS. 2A-2B, FIGS. 3A-3B, and FIGS. 4A-4B. Although shown in a logical order, the arrangement and numbering of the steps of FIGS. 6-7 are not intended to be limited.

Referring to FIG. 6, step 610 of a method 600 of forming a stacked PIC die provides a first PIC die comprising a first plurality of contact pads. Each contact pad of the first plurality of contact pads comprises a first electrical contact region comprising a first plurality of electrical contacts overfilled with a first metal layer, a first optical contact region covered by a first dielectric layer and the first metal layer, and a first transition region disposed between the first electrical contact region and the first optical contact region. The first transition region comprises a first plurality of dummy contacts overfilled with the first metal layer. For example, the first contact pad 100 illustrated in FIG. 1A may be each contact pad of the first plurality of contact pads of the first PIC die described in step 610 of the method 600 of FIG. 6. Further, the components described for each contact pad of the first plurality of contact pads of step 610 of FIG. 6 may be the elements illustrated for the first contact pad 100 of FIG. 1A, such as the first metal layer of step 610 may be the first metal layer 102a of FIG. 1A, and etcetera.

Still referring to FIG. 6, step 620 of the method 600 performs a chemical mechanical planarization (CMP) process on the first PIC die to form a first planarized surface. The CMP process may be the same planarization process to planarize the first contact pad 100 of FIG. 1A and form the first contact pad 100 of FIG. 1B. The step 620 forms the first planarized surface where the first metal layer is removed and the first dielectric layer is planarized at a different rate than the first metal layer. The material of the first metal layer is removed more rapidly than the material of the first dielectric layer. To prevent a drastic change in height between the first electrical contact region and the first optical contact region, the first transition region strategically varies properties of the first plurality of dummy contacts such that there is a smooth transition in height between the first electrical contact region and the first optical contact region. In an embodiment, the first transition region may vary the pad density of the dummy contacts, such as illustrated in FIGS. 2A-2B. In other embodiments, the first transition region may vary the size of the dummy contacts, such as illustrated in FIGS. 3A-3B. In various other embodiments, the first transition region may vary both the size of and the pad density of the dummy contacts, such as illustrated in FIGS. 4A-4B.

After performing the CMP process in step 620, the method 600 provides a second PIC die comprising a second plurality of contact pads in step 630. Each contact pad of the second plurality of contact pads comprises a second electrical contact region comprising a second plurality of electrical contacts overfilled with a second metal layer, a second optical contact region covered by a second dielectric layer and the second metal layer, and a second transition region disposed between the second electrical contact region and the second optical contact region. The second transition region comprises a second plurality of dummy contacts overfilled with the second metal layer. For example, the second contact pad 150 illustrated in FIGS. 1C may be each contact pad of the second plurality of contact pads of the second PIC die described in step 640 of the method 600 of FIG. 6. Further, the components described for each contact pad of the second plurality of contact pads of step 630 of FIG. 6 may be the elements illustrated for the second contact pad 150 of FIG. 1C, such as the second plurality of electrical contacts of step 630 may be the second plurality of electrical contacts 108b of FIG. 1C, and etcetera.

The method 600 performs the CMP process on the second PIC die to form a second planarized surface in step 640. Again, the step 640 forms the second planarized surface where the second metal layer is removed and the second dielectric layer is planarized at a different rate than the second metal layer. The material of the second metal layer is removed more rapidly than the material of the second dielectric layer. To prevent a drastic change in height between the second electrical contact region and the second optical contact region, the second transition region strategically varies properties of the second plurality of dummy contacts such that there is a smooth transition in height between the second electrical contact region and the second optical contact region. In an embodiment, the second transition region may vary the pad density of the dummy contacts, such as illustrated in FIGS. 2A-2B. In other embodiments, the second transition region may vary the size of the dummy contacts, such as illustrated in FIGS. 3A-3B. In various other embodiments, the second transition region may vary both the size of and the pad density of the dummy contacts, such as illustrated in FIGS. 4A-4B.

After performing the CMP process to form the second planarized surface in step 640, the method 600 bonds the first planarized surface of the first PIC die to the second planarized surface of the second PIC die to form the stacked PIC die in step 650. The first PIC die and the second PIC die may be bonded using a combination of hybrid bonding and fusion bonding to form photonic evanescent couplings between the optical contact regions. Further, the stacked PIC die comprises bonded contact pads, and the bonded contact pads may be the bonded first contact pad 100 and second contact pad 150 illustrated in FIG. 1E.

In various embodiments, the bonding process forms electrical contacts between the first electrical contact region of the first PIC die and the second electrical contact region of the second PIC die. Further, the bonding process forms dummy contacts between the first plurality of dummy contacts of the first PIC die and the second plurality of dummy contacts of the second PIC die. And the bonding process forms optical contacts between the first optical contact regions of the first PIC die and the second optical contact regions of the second PIC die. In various embodiments, the first optical contact regions and the second optical contact regions comprise optical components such as waveguides, and the optical contacts formed from the bonding process may be evanescent photonic couplings between waveguides of the first PIC die and the second PIC die.

Now referring to FIG. 7, step 710 of a method 700 receives a first photonic integrated circuit (PIC) die comprising a first plurality of contact pads. Each contact pad of the first plurality of contact pads comprises a first electrical contact region comprising a first plurality of electrical contacts, a first optical contact region, and a first transition region disposed between the first electrical contact region and the first optical contact region. The first transition region comprises a first plurality of dummy contacts. For example, the first contact pad 100 illustrated in FIG. 1B may be each contact pad of the first plurality of contact pads of the first PIC die described in step 710 of the method 700 of FIG. 7. Further, the components described for each contact pad of the first plurality of contact pads of step 710 of FIG. 7 may be the elements illustrated for the first contact pad 100 of FIG. 1B, such as the first plurality of electrical contacts of step 710 may be the first plurality of electrical contacts 108a of FIG. 1B, and etcetera.

To prevent a drastic change in height between the first electrical contact region and the first optical contact region, the first transition region strategically varies properties of the first plurality of dummy contacts such that there is a smooth transition in height between the first electrical contact region and the first optical contact region. In an embodiment, the first transition region may vary the pad density of the dummy contacts, such as illustrated in FIGS. 2A-2B. In other embodiments, the first transition region may vary the size of the dummy contacts, such as illustrated in FIGS. 3A-3B. In various other embodiments, the first transition region may vary both the size of and the pad density of the dummy contacts, such as illustrated in FIGS. 4A-4B.

Still referring to FIG. 7, step 720 of the method 700 receives a second PIC die comprising a second plurality of contact pads. Each contact pad of the second plurality of contact pads comprises a second electrical contact region comprising a second plurality of electrical contacts, a second optical contact region, and a second transition region disposed between the second electrical contact region and the second optical contact region. The second transition region comprises a second plurality of dummy contacts. For example, the second contact pad 150 illustrated in FIG. 1C may be each contact pad of the second plurality of contact pads of the second PIC die described in step 720 of the method 700 of FIG. 7. Further, the components described for each contact pad of the second plurality of contact pads of step 720 of FIG. 7 may be the elements illustrated for the second contact pad 150 of FIG. 1C, such as the second plurality of electrical contacts of step 720 may be the second plurality of electrical contacts 108b of FIG. 1C, and etcetera.

To prevent a drastic change in height between the second electrical contact region and the second optical contact region, the second transition region strategically varies properties of the second plurality of dummy contacts such that there is a smooth transition in height between the second electrical contact region and the second optical contact region. In an embodiment, the second transition region may vary the pad density of the dummy contacts, such as illustrated in FIGS. 2A-2B. In other embodiments, the second transition region may vary the size of the dummy contacts, such as illustrated in FIGS. 3A-3B. In various other embodiments, the second transition region may vary both the size of and the pad density of the dummy contacts, such as illustrated in FIGS. 4A-4B.

After, the method 700 proceeds to step 730. In step 730, the method 700 bonds the first PIC die with the second PIC die to form a stacked PIC die. The first PIC die and the second PIC die may be bonded using a combination of hybrid bonding and fusion bonding to form photonic evanescent couplings between the optical contact regions. Further, the stacked PIC die comprises bonded contact pads, and the bonded contact pads may be the bonded first contact pad 100 and second contact pad 150 illustrated in FIG. 1E.

In various embodiments, the bonding process forms electrical contacts between the first electrical contact region of the first PIC die and the second electrical contact region of the second PIC die. Further, the bonding process forms dummy contacts between the first plurality of dummy contacts of the first PIC die and the second plurality of dummy contacts of the second PIC die. And the bonding process forms optical contacts between the first optical contact regions of the first PIC die and the second optical contact regions of the second PIC die. In various embodiments, the first optical contact regions and the second optical contact regions comprise optical components such as waveguides, and the optical contacts formed from the bonding process may be evanescent photonic couplings between waveguides of the first PIC die and the second PIC die.

As identified by the inventors, the method of forming stacked PIC dies of this disclosure prevents void formation which may occur when using a conventional bonding process without density gradation between optical and electrical contact regions. FIGS. 8A-8D illustrate the difficulty identified by the inventors of this disclosure in conventional methods (methods without a density gradation of dummy contacts between the electrical and optical contact regions) which cause voids to be formed between contact pads of stacked PIC dies. For FIGS. 8A-8D, similarly labeled elements may be as previously described.

A conventional method may start with a first PIC die comprising a first contact pad 800 illustrated in the cross-sectional view of FIG. 8A. The difference between the first contact pad 800 and the first contact pad 100 illustrated in FIG. 1A are a first transition region 816a of FIG. 8A comprises a first plurality of dummy contacts 810a with no density gradation from the first electrical contact region 114a to the first optical contact region 118a. Rather, the first transition region 816a comprises the first plurality of dummy contacts 810a with the same pitch and pattern density as the first electrical contact region 114a.

Consequently, the conventional method will planarize the first electrical contact regions 114a and the first transition region 816a at approximately the same planarization rate while planarizing the first optical contact region 118a at a different rate, which results in a large step height difference between the first optical contact region 118a and the first transition region 816a. And because there is no density gradation of the first plurality of dummy contacts 810a in the first transition region 816a from the first electrical contact region 114a, there is a sharp transition (drastic difference in metal material density) between the first optical contact region 118a and the first transition region 816a.

FIG. 8B illustrates the first contact pad 800 after planarization (such as described for FIGS. 1A-1B) which formed a drastic step height difference between the first optical contact region 118a and the first transition region 816a to form a first planarized surface 820a. In contrast to the first planarized surface 120a of FIG. 1B, the first planarized surface 820a of FIG. 8B comprises a drastic step height difference between the regions due to the different planarization rates. FIG. 8C illustrates the first contact pad 800 being aligned for bonding with a second contact pad 850 that may have been planarized in a similar process. After aligning the first contact pad 800 and the second contact pad 850, a bonding process may be started which propagates a bonding front 140 between the surfaces of the contact pads. And FIG. 8D illustrates the bond front 140 propagating between the first contact pad 800 and the second contact pad 850.

As illustrated in FIG. 8D, the drastic step height difference between the first optical contact region 118a and the first transition region 816a forms voids 802 (regions not in physical contact) which may prevent successful evanescent photonic coupling between the optical contact regions. The embodiment methods of forming a stacked PIC die of this disclosure, such as described using FIGS. 1A-1E, may be used to prevent void formation and improve the efficiency of stacked PIC die fabrication.

Example embodiments of the invention are described below. Other embodiments can also be understood from the entirety of the specification as well as the claims filed herein.

Example 1. A photonic integrated circuit (PIC) device includes a first PIC die including a first plurality of contact pads, each first contact pad includes a first electrical contact region including a first plurality of electrical contacts, a first optical contact region, and a first transition region disposed between the first electrical contact region and the first optical contact region, the first transition region includes a first plurality of dummy contacts.

Example 2. The PIC device of example 1, further includes a second PIC die including a second plurality of contact pads, each second contact pad includes a second electrical contact region including a second plurality of electrical contacts, a second optical contact region, and a second transition region disposed between the second electrical contact region and the second optical contact region, the second transition region includes a second plurality of dummy contacts. And the PIC device further includes a bond coupling the first PIC die with the second PIC die to form the PIC device.

Example 3. The PIC device of one of examples 1 or 2, where the bond includes interconnects between the first PIC die and the second PIC die, each interconnect including an optical coupler between the first optical contact region and the second optical contact region, an electrical coupler between each of the first plurality of electrical contacts and the second plurality of electrical contacts, and a dummy coupler between each of the first plurality of dummy contacts and the second plurality of dummy contacts.

Example 4. The PIC device of one of examples 1 to 3, where the optical coupler includes an evanescent photonic coupling between a first waveguide of the first optical contact region and a second waveguide of the second optical contact region.

Example 5. The PIC device of one of examples 1 to 4, where the first plurality of dummy contacts decreases a pad density of the first plurality of dummy contacts from the first electrical contact region to the first optical contact region. And where the second plurality of dummy contacts decreases the pad density of the second plurality of dummy contacts from the second electrical contact region to the second optical contact region.

Example 6. The PIC device of one of examples 1 to 5, where the first plurality of dummy contacts decreases a critical dimension of the first plurality of dummy contacts from the first electrical contact region to the first optical contact region. And where the second plurality of dummy contacts decreases the critical dimension of the second plurality of dummy contacts from the second electrical contact region to the second optical contact region.

Example 7. The PIC device of one of examples 1 to 6, where the first plurality of dummy contacts decreases a pad density and a critical dimension of the first plurality of dummy contacts from the first electrical contact region to the first optical contact region. And where the second plurality of dummy contacts decreases the pad density and the critical dimension of the second plurality of dummy contacts from the second electrical contact region to the second optical contact region.

Example 8. The PIC device of one of examples 1 to 7, where the first plurality of electrical contacts include through dielectric vias (TDVs).

Example 9. A method for fabricating a stacked photonic integrated circuit (PIC) die includes receiving a first PIC die including a first plurality of contact pads, each first contact pad includes a first electrical contact region including a first plurality of electrical contacts, a first optical contact region, and a first transition region disposed between the first electrical contact region and the first optical contact region, the first transition region includes a first plurality of dummy contacts. The method further includes receiving a second PIC die including a second plurality of contact pads, each second contact pad includes a second electrical contact region including a second plurality of electrical contacts, a second optical contact region, and a second transition region disposed between the second electrical contact region and the second optical contact region, the second transition region includes a second plurality of dummy contacts. And the method further includes bonding the first PIC die with the second PIC die to form the stacked PIC die.

Example 10. The method of example 9, where the first plurality of dummy contacts decreases a pad density of the first plurality of dummy contacts from the first electrical contact region to the first optical contact region. And where the second plurality of dummy contacts decreases the pad density of the second plurality of dummy contacts from the second electrical contact region to the second optical contact region.

Example 11. The method of one of examples 9 or 10, where the first plurality of dummy contacts decreases a critical dimension of the first plurality of dummy contacts from the first electrical contact region to the first optical contact region. And where the second plurality of dummy contacts decreases the critical dimension of the second plurality of dummy contacts from the second electrical contact region to the second optical contact region.

Example 12. The method of one of examples 9 to 11, where the first plurality of dummy contacts decreases a pad density and a critical dimension of the first plurality of dummy contacts from the first electrical contact region to the first optical contact region. And where the second plurality of dummy contacts decreases the pad density and the critical dimension of the second plurality of dummy contacts from the second electrical contact region to the second optical contact region.

Example 13. A method for fabricating a photonic integrated circuit (PIC) includes providing a first PIC die including a first plurality of contact pads, each first contact pad includes a first electrical contact region including a first plurality of electrical contacts overfilled with a first metal layer, a first optical contact region covered by a first dielectric layer and the first metal layer, and a first transition region disposed between the first electrical contact region and the first optical contact region, the first transition region includes a first plurality of dummy contacts overfilled with the first metal layer. The method further includes performing a chemical mechanical planarization (CMP) process on the first PIC die to form a first planarized surface. The method further includes providing a second PIC die including a second plurality of contact pads, each second contact pad includes a second electrical contact region including a second plurality of electrical contacts overfilled with a second metal layer, a second optical contact region covered by a second dielectric layer and the second metal layer, and a second transition region disposed between the second electrical contact region and the second optical contact region, the second transition region includes a second plurality of dummy contacts overfilled with the second metal layer. The method further includes performing the CMP process on the second PIC die to form a second planarized surface. And the method further includes bonding the first planarized surface of the first PIC die to the second planarized surface of the second PIC die to form a stacked PIC die.

Example 14. The method of example 13, where the first plurality of dummy contacts decreases a pad density of the first plurality of dummy contacts from the first electrical contact region to the first optical contact region. And where the second plurality of dummy contacts decreases the pad density of the second plurality of dummy contacts from the second electrical contact region to the second optical contact region.

Example 15. The method of one of examples 13 or 14, where the first plurality of dummy contacts decreases a critical dimension of the first plurality of dummy contacts from the first electrical contact region to the first optical contact region. And where the second plurality of dummy contacts decreases the critical dimension of the second plurality of dummy contacts from the second electrical contact region to the second optical contact region.

Example 16. The method of one of examples 13 to 15, where the first plurality of dummy contacts decreases a pad density and a critical dimension of the first plurality of dummy contacts from the first electrical contact region to the first optical contact region. And where the second plurality of dummy contacts decreases the pad density and the critical dimension of the second plurality of dummy contacts from the second electrical contact region to the second optical contact region.

Example 17. The method of one of examples 13 to 16, where the first optical contact region includes a first alignment mark and the second optical contact region includes a second alignment mark.

Example 18. The method of one of examples 13 to 17, where the first electrical contact region is planarized to a first height, the first optical contact region is planarized to a second height, and the first transition region is planarized to a plurality of heights for the first plurality of dummy contacts such that there is a smooth transition between the first height of the first electrical contact region to the second height of the first optical contact region.

Example 19. The method of one of examples 13 to 18, where bonding the first planarized surface to the second planarized surface includes, before the bonding, aligning the first PIC die to the second PIC die to align the first optical contact regions of the first plurality of contact pads of the first PIC die to the second optical contact regions of the second plurality of contact pads of the second PIC die.

Example 20. The method of one of examples 13 to 19, where the first optical contact region is bonded to a corresponding second optical contact region to form an optical coupler. Where the first electrical contact region is bonded to a corresponding second electrical contact region to form an electrical coupler. And where the first transition region is bonded to a corresponding second transition region to form a dummy coupler.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A photonic integrated circuit (PIC) device comprising:
a first PIC die comprising a first plurality of contact pads, each first contact pad comprising a first electrical contact region comprising a first plurality of electrical contacts, a first optical contact region, and a first transition region disposed between the first electrical contact region and the first optical contact region, the first transition region comprising a first plurality of dummy contacts.

2. The PIC device of claim 1, further comprising:
a second PIC die comprising a second plurality of contact pads, each second contact pad comprising a second electrical contact region comprising a second plurality of electrical contacts, a second optical contact region, and a second transition region disposed between the second electrical contact region and the second optical contact region, the second transition region comprising a second plurality of dummy contacts; and
a bond coupling the first PIC die with the second PIC die to form the PIC device.

3. The PIC device of claim 2, wherein the bond comprises interconnects between the first PIC die and the second PIC die, each interconnect comprising an optical coupler between the first optical contact region and the second optical contact region, an electrical coupler between each of the first plurality of electrical contacts and the second plurality of electrical contacts, and a dummy coupler between each of the first plurality of dummy contacts and the second plurality of dummy contacts.

4. The PIC device of claim 3, wherein the optical coupler comprises an evanescent photonic coupling between a first waveguide of the first optical contact region and a second waveguide of the second optical contact region.

5. The PIC device of claim 2,
wherein the first plurality of dummy contacts decreases a pad density of the first plurality of dummy contacts from the first electrical contact region to the first optical contact region; and
wherein the second plurality of dummy contacts decreases the pad density of the second plurality of dummy contacts from the second electrical contact region to the second optical contact region.

6. The PIC device of claim 2,
wherein the first plurality of dummy contacts decreases a critical dimension of the first plurality of dummy contacts from the first electrical contact region to the first optical contact region; and
wherein the second plurality of dummy contacts decreases the critical dimension of the second plurality of dummy contacts from the second electrical contact region to the second optical contact region.

7. The PIC device of claim 2,
wherein the first plurality of dummy contacts decreases a pad density and a critical dimension of the first plurality of dummy contacts from the first electrical contact region to the first optical contact region; and
wherein the second plurality of dummy contacts decreases the pad density and the critical dimension of the second plurality of dummy contacts from the second electrical contact region to the second optical contact region.

8. The PIC device of claim 2, wherein the first plurality of electrical contacts comprise through dielectric vias (TDVs).

9. A method for fabricating a stacked photonic integrated circuit (PIC) die, the method comprising:
receiving a first PIC die comprising a first plurality of contact pads, each first contact pad comprising a first electrical contact region comprising a first plurality of electrical contacts, a first optical contact region, and a first transition region disposed between the first electrical contact region and the first optical contact region, the first transition region comprising a first plurality of dummy contacts;
receiving a second PIC die comprising a second plurality of contact pads, each second contact pad comprising a second electrical contact region comprising a second plurality of electrical contacts, a second optical contact region, and a second transition region disposed between the second electrical contact region and the second optical contact region, the second transition region comprising a second plurality of dummy contacts; and
bonding the first PIC die with the second PIC die to form the stacked PIC die.

10. The method of claim 9,
wherein the first plurality of dummy contacts decreases a pad density of the first plurality of dummy contacts from the first electrical contact region to the first optical contact region; and
wherein the second plurality of dummy contacts decreases the pad density of the second plurality of dummy contacts from the second electrical contact region to the second optical contact region.

11. The method of claim 9,
wherein the first plurality of dummy contacts decreases a critical dimension of the first plurality of dummy contacts from the first electrical contact region to the first optical contact region; and
wherein the second plurality of dummy contacts decreases the critical dimension of the second plurality of dummy contacts from the second electrical contact region to the second optical contact region.

12. The method of claim 9,
wherein the first plurality of dummy contacts decreases a pad density and a critical dimension of the first plurality of dummy contacts from the first electrical contact region to the first optical contact region; and
wherein the second plurality of dummy contacts decreases the pad density and the critical dimension of the second plurality of dummy contacts from the second electrical contact region to the second optical contact region.

13. A method for fabricating a photonic integrated circuit (PIC), the method comprising:
providing a first PIC die comprising a first plurality of contact pads, each first contact pad comprising a first electrical contact region comprising a first plurality of electrical contacts overfilled with a first metal layer, a first optical contact region covered by a first dielectric layer and the first metal layer, and a first transition region disposed between the first electrical contact region and the first optical contact region, the first transition region comprising a first plurality of dummy contacts overfilled with the first metal layer;
performing a chemical mechanical planarization (CMP) process on the first PIC die to form a first planarized surface;
providing a second PIC die comprising a second plurality of contact pads, each second contact pad comprising a second electrical contact region comprising a second plurality of electrical contacts overfilled with a second metal layer, a second optical contact region covered by a second dielectric layer and the second metal layer, and a second transition region disposed between the second electrical contact region and the second optical contact region, the second transition region comprising a second plurality of dummy contacts overfilled with the second metal layer;
performing the CMP process on the second PIC die to form a second planarized surface; and
bonding the first planarized surface of the first PIC die to the second planarized surface of the second PIC die to form a stacked PIC die.

14. The method of claim 13,
wherein the first plurality of dummy contacts decreases a pad density of the first plurality of dummy contacts from the first electrical contact region to the first optical contact region; and
wherein the second plurality of dummy contacts decreases the pad density of the second plurality of dummy contacts from the second electrical contact region to the second optical contact region.

15. The method of claim 13,
wherein the first plurality of dummy contacts decreases a critical dimension of the first plurality of dummy contacts from the first electrical contact region to the first optical contact region; and
wherein the second plurality of dummy contacts decreases the critical dimension of the second plurality of dummy contacts from the second electrical contact region to the second optical contact region.

16. The method of claim 13,
wherein the first plurality of dummy contacts decreases a pad density and a critical dimension of the first plurality of dummy contacts from the first electrical contact region to the first optical contact region; and
wherein the second plurality of dummy contacts decreases the pad density and the critical dimension of the second plurality of dummy contacts from the second electrical contact region to the second optical contact region.

17. The method of claim 13, wherein the first optical contact region comprises a first alignment mark and the second optical contact region comprises a second alignment mark.

18. The method of claim 13, wherein the first electrical contact region is planarized to a first height, the first optical contact region is planarized to a second height, and the first transition region is planarized to a plurality of heights for the first plurality of dummy contacts such that there is a smooth transition between the first height of the first electrical contact region to the second height of the first optical contact region.

19. The method of claim 13, wherein bonding the first planarized surface to the second planarized surface comprises, before the bonding, aligning the first PIC die to the second PIC die to align the first optical contact regions of the first plurality of contact pads of the first PIC die to the second optical contact regions of the second plurality of contact pads of the second PIC die.

20. The method of claim 13,
wherein the first optical contact region is bonded to a corresponding second optical contact region to form an optical coupler;
wherein the first electrical contact region is bonded to a corresponding second electrical contact region to form an electrical coupler; and
wherein the first transition region is bonded to a corresponding second transition region to form a dummy coupler.
